(19) United States
(12) Patent Application Publication
(10) Pub. No.: US 2007/0075366 A1
(43) Pub. Date: Apr. 5, 2007

(54) Semiconductor memory device and method for manufacturing the same

(75) Inventor: Takeshi Hamamoto, Yokohama-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Minato-ku (JP)

(21) Appl. No.: 11/304,681

(22) Filed: Dec. 16, 2005

(30) Foreign Application Priority Data
Oct. 3, 2005 (JP) 2005-289972

(51) Int. Cl. H01L 27/12; H01L 27/01

(52) U.S. Cl. 257/347

(57) ABSTRACT

According to the present invention, there is provided a semiconductor memory device having: a semiconductor layer of a first conductivity type formed above a semiconductor substrate via an embedded insulation film, a gate electrode formed above the semiconductor layer via a gate insulation film, a floating body region of a first conductivity type formed under the gate electrode in the semiconductor layer of a first conductivity type, which functions as a collector region of a first conductivity type, a source region of a second conductivity type and a drain region of a second conductivity type formed on both sides of the floating body region in the semiconductor layer, the drain region functioning as a base region of a second conductivity type, an emitter region of a first conductivity type formed in the semiconductor layer, adjacent to the side opposite to the side of the floating body region in the drain region, and silicide formed at least on the surface portion of the source region.

### CROSS REFERENCE TO RELATED APPLICATIONS

This application is based upon and claims benefit of priority under 35 USC 119 from the Japanese Patent Application No. 2005-289972, filed on Oct. 3, 2005, the entire contents of which are incorporated herein by reference.

### BACKGROUND OF THE INVENTION

The present invention relates to a semiconductor memory device and a method for manufacturing the same.

Recently, a floating body cell (FBC) memory has been developed as a semiconductor memory substituting DRAM. The FBC memory has a transistor formed on a silicon-on-insulator (SOI) substrate, stores data “1” by accumulating holes in a floating body of the formed transistor, and stores data “0” by discharging the holes from the floating body.

A method for writing data “1” in an FBC has been proposed, wherein holes are injected in a floating body using a bipolar transistor (e.g., refer to Patent Document 1).

Such an FBC is built up, for example, by forming a PNP bipolar transistor adjacent to an NMOSFET formed on an SOI substrate.

Specifically, in the FBC, a P-type floating body in an electrically floating state is formed above a semiconductor substrate via an embedded insulation film, and a gate electrode is formed above the P-type floating body via a gate insulation film. Further in the FBC, a channel region is formed on the surface portion of the P-type floating body, and an N-type source region and an N-type drain region are formed on both sides of the P-type floating body.

Furthermore, a P-type emitter region is formed adjacent to the side opposite to the P-type floating body side in the N-type drain region, and by making the N-type drain region in the FBC operate as an N-type base region and making the P-type floating body operate as a P-type collector region, a PNP bipolar transistor is formed.

In the case of such an FBC, by connecting the P-type emitter region of the PNP bipolar transistor to an emitter line, and by applying a positive potential to the emitter line to inject holes from the P-type emitter region through the N-type base region (N-type drain region) into the P-type collector region (P-type floating body), holes can be accumulated in the P-type floating body.

However, there has been a problem that the addition of a bipolar transistor to the FBC enlarges the cell size of a memory cell.

The title of a reference related to a method for writing data “1” in an FBC using a bipolar transistor is:

Japanese Patent Laid-Open No. 2005-79314.

### SUMMARY OF THE INVENTION

According to one aspect of the present invention, there is provided a semiconductor memory device comprising:

a semiconductor layer of a first conductivity type formed above a semiconductor substrate via an embedded insulation film,

a gate electrode formed above the semiconductor layer via a gate insulation film,

a floating body region of a first conductivity type formed under the gate electrode in the semiconductor layer of a first conductivity type, which functions as a collector region of a first conductivity type,

a source region of a second conductivity type and a drain region of a second conductivity type formed on both sides of the floating body region in the semiconductor layer, the drain region functioning as a base region of a second conductivity type,

an emitter region of a first conductivity type formed in the semiconductor layer, adjacent to the side opposite to the side of the floating body region in the drain region, and

silicide formed at least on the surface portion of the source region.

According to one aspect of the present invention, there is provided a semiconductor memory device comprising:

a semiconductor layer of a first conductivity type formed above a semiconductor substrate via an embedded insulation film,

a gate electrode formed above the semiconductor layer via a gate insulation film,

a floating body region of a first conductivity type formed under the gate electrode in the semiconductor layer of a first conductivity type, which functions as a collector region of a first conductivity type,

a source region of a second conductivity type and a drain region of a second conductivity type formed on both sides of the floating body region in the semiconductor layer, the drain region functioning as a base region of a second conductivity type, and

an emitter region of a first conductivity type formed in the semiconductor layer, adjacent to the side opposite to the side of the floating body region in the drain region, wherein

the source region has a crystal defect.

According to one aspect of the present invention, there is provided a method for manufacturing a semiconductor memory device comprising:

forming a semiconductor layer of a first conductivity type above a semiconductor substrate via an embedded insulation film,

forming a gate electrode above the semiconductor layer via a gate insulation film,

forming a first mask having a desired pattern, forming a source region and a drain region of a second conductivity type by the ion implantation of an impurity into the semiconductor layer using the first mask and the gate electrode as masks,

forming a second mask having a desired pattern, forming an emitter region of a first conductivity type adjacent to the drain region by the ion implantation of an impurity into the semiconductor layer using the second mask, and

forming suicide at least on the surface portion of the source region.

### BRIEF DESCRIPTION OF THE DRAWINGS

FIG. 1 is a top view showing the configuration of a memory cell array according to the first embodiment of the present invention;

FIG. 2 is a top view and a sectional view showing the configuration of an FBC according to the first embodiment of the present invention;

FIG. 3 is a top view showing the configuration of a memory cell array according to a comparative example;

FIG. 4 is a top view and a sectional view showing the configuration of an FBC according to a comparative example;

FIG. 5 is a vertical sectional view showing the sectional structure of an element in a stage of the process in a method for manufacturing an FBC according to the first embodiment of the present invention;

FIG. 6 is a vertical sectional view showing the sectional structure of the element in another stage of the process for manufacturing the FBC;

FIG. 7 is a vertical sectional view showing the sectional structure of the element in another stage of the process for manufacturing the FBC;

FIG. 8 is a vertical sectional view showing the sectional structure of the element in another stage of the process for manufacturing the FBC;

FIG. 9 is a vertical sectional view showing the sectional structure of the element in another stage of the process for manufacturing the FBC;

FIG. 10 is a vertical sectional view showing the sectional structure of the element in another stage of the process for manufacturing the FBC;

FIG. 11 is a vertical sectional view showing the sectional structure of the element in another stage of the process for manufacturing the FBC;

FIG. 12 is a vertical sectional view showing the sectional structure of the element in another stage of the process for manufacturing the FBC;

FIG. 13 is a top view and a sectional view showing the configuration of an FBC according to the second embodiment of the present invention;

FIG. 14 is a top view and a sectional view showing the configuration of an FBC according to the third embodiment of the present invention;

FIG. 15 is a vertical sectional view showing the sectional structure of the element in a stage of the process for manufacturing the FBC;

FIG. 16 is a vertical sectional view showing the sectional structure of the element in another stage of the process for manufacturing the FBC;

FIG. 17 is a vertical sectional view showing the sectional structure of the element in another stage of the process for manufacturing the FBC;

FIG. 18 is a vertical sectional view showing the sectional structure of the element in another stage of the process in the same method for manufacturing an FBC; and

FIG. 19 is a top view and a sectional view showing the configuration of an FBC according to the fourth embodiment of the present invention.

### DETAILED DESCRIPTION OF THE INVENTION

The embodiments of the present invention will be described below referring to the drawings.

(1) First Embodiment

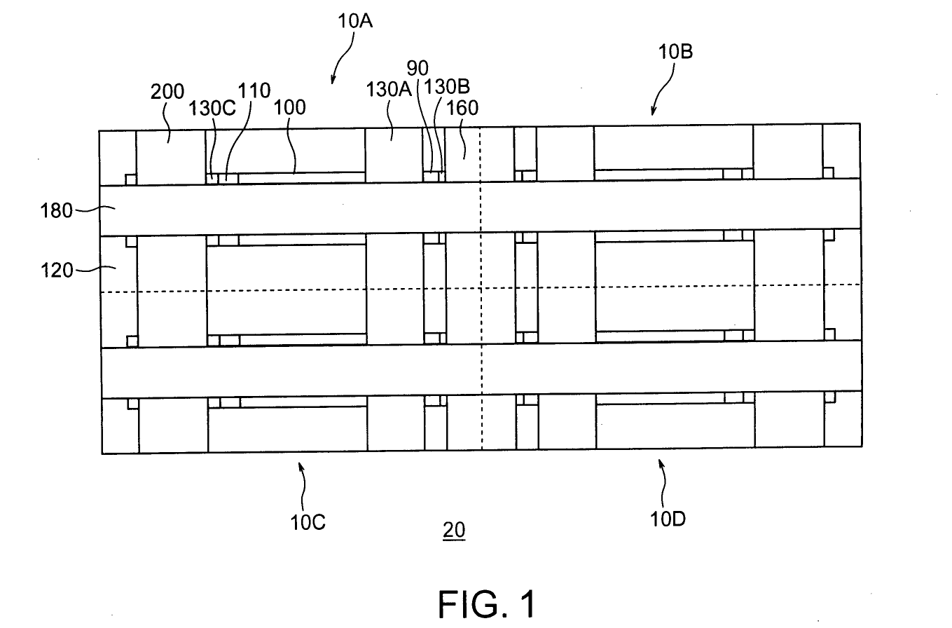

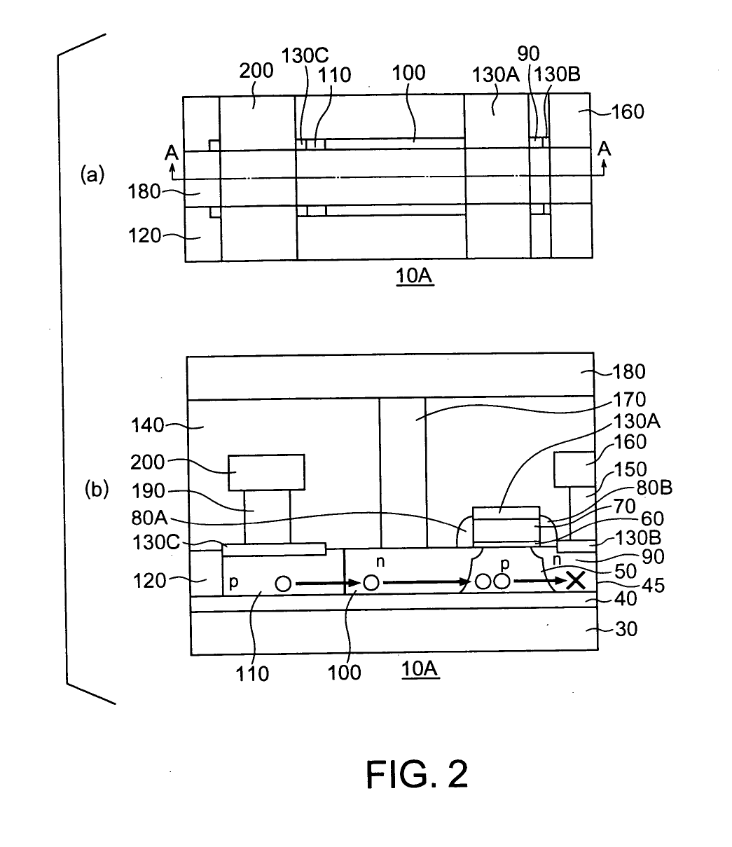

FIG. 1 shows apart of the configuration of a memory cell array 20 formed by disposing FBCs 10A to 10N according to the first embodiment of the present invention in a matrix; and FIG. 2 shows the configuration of an FBC 10A according to the first embodiment.

FIG. 1 shows a top view of a region in the memory cell array 20 where four FBCs, FBCs 10A to 10D, are formed when viewed from above, FIG. 2(a) shows a top view of a region where an FBC, FBC 10A, is formed when viewed from above, and FIG. 2(b) shows a vertical sectional view when FBC 10A is cut along the line A-A.

Such FBC 10A is composed by forming a PNP bipolar transistor adjacent to an NMOSFET formed on an SOI substrate.

Specifically, in the FBC 10A, a P-type floating body 50 in an electrically floating state is formed in a semiconductor layer 45 formed above a semiconductor substrate 30 via an embedded insulation film 40. The semiconductor layer 50 is formed so as to have a thickness of equal to or less than 100 nm. Furthermore, above the P-type floating body 50, a gate electrode 70 as a word line is formed via a gate insulation film 60, and on the side of the gate electrode 70, sidewall insulation films 80A and 80B are formed.

In the FBC 10A, a channel region (not shown) is formed on the surface portion of the P-type floating body 50, and an N-type source region 90 and an N-type drain region 100 are formed on both sides of the P-type floating body 50.

A P-type emitter region 110 is formed adjacent to the side opposite to the side of the P-type floating body 50 in the N-type drain region 100; and by operating the N-type drain region 100 of the FBC 10A as an N-type base region, and by operating the P-type floating body 50 as a P-type collector region, a PNP bipolar transistor is formed. An element-isolating insulation film 120 is formed around the element region consisting of the P-type floating body 50, the N-type source region 90, the N-type drain region 100, and the P-type emitter region 110.

On the surfaces of the gate electrode 70, the N-type source region 90, and the P-type emitter region 110, silicide 130A to 130C is formed to reduce parasitic resistance, and the silicide 130A to 130C is composed of, for example, cobalt (Co), nickel (Ni) or the like, and the thickness thereof is, for example, about 25 nm. Among these, in the N-type source region 90 on which the silicide 130B is formed, the distance between the bottom surface of the suicide 130B and the upper surface of the embedded insulation film 40 (i.e., the thickness of the N-type source region 90) is formed to be equal to or less than 80 nm.

The silicide 130B is formed by consuming the semiconductor layer 45 composed of silicon. Therefore, for example, when the thickness of the silicide 130B is about 25 nm and the thickness of the semiconductor layer 45 is about 55 nm, the thickness of the N-type source region 90 is about 30 nm. On the upper surfaces of the suicide 130A to 130C, an interlayer insulation film 140 is formed.

The silicide 130B formed on the surface of the N-type source region 90 is coupled to a source line 160 as a ground line via a contact plug 150, the N-type drain region 100 is coupled to a bit line 180 via a contact plug 170, and the silicide 130C formed on the surface of the P-type emitter region 110 is coupled to an emitter line 200 via a contact plug 190.

When data “1” is written in the FBC 10A, by supplying a positive potential to the emitter line 200 to make the N-type drain region 100 operate as an N-type base region and to make the P-type floating body 50 as a P-type collector region, and by injecting holes from the P-type emitter region 110 through the N-type drain region 100 into the P-type floating body 50, the holes are accumulated in the P-type floating body 50.

In the case of the first embodiment, the semiconductor layer 45 is formed so as to have a thickness of equal to or less than 100 nm, the N-type source region 90 is formed so as to have a thickness of equal to or less than 80 nm, and both the regions are formed to have a thin thickness. As described above, if at least the thickness of the semiconductor layer 45 is equal to or less than 100 nm, or the thickness of the N-type source region 90 is equal to or less than 80 nm, even if the holes accumulated in the P-type floating body 50 flow into the N-type source region 90, they bond to electrons present in the N-type source region 90 and disappear.

Thereby, the occurrence of a phenomenon wherein holes go through the N-type source region 90 and flow into the P-type floating body (not shown) of the FBC 10B adjacent to the N-type source region 90, known as “bipolar disturb” can be suppressed.

Therefore, as in the first embodiment, the FBC 10A can share the N-type source region 90, the silicide 130B, the contact plug 150, and the source line 160 with the FBC 10B adjoining in the direction of the bit line 180.

If the thickness of the semiconductor layer 45 exceeds 100 nm, and the thickness of the N-type source region 90 exceeds 80 nm, a problem of the occurrence of bipolar disturb wherein holes go through the N-type source region 90 and flow into the P-type floating body of the FBC 10B adjacent to the N-type source region 90 arises.

Incidentally, since no silicide is formed on the surface of the N-type drain region 100, the N-type drain region 100 is thicker than the N-type source region 90 by the thickness of the silicide 130. Therefore, it can be suppressed that holes traveling from the P-type emitter region 100 toward the P-type floating body 50 bond to electrons present in the N-type drain region 100 and disappear.

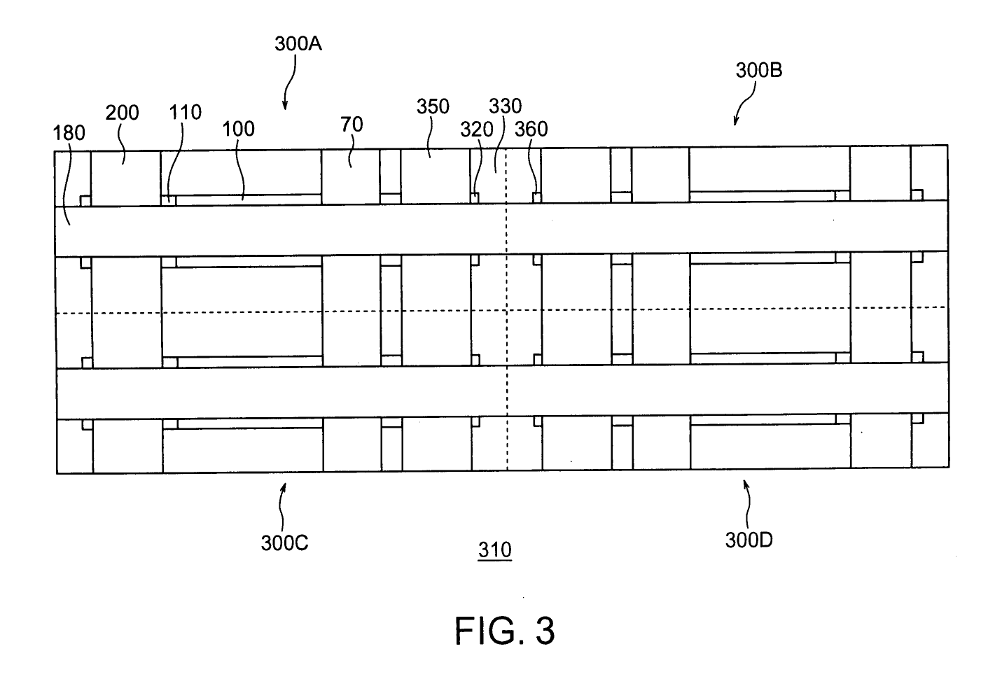

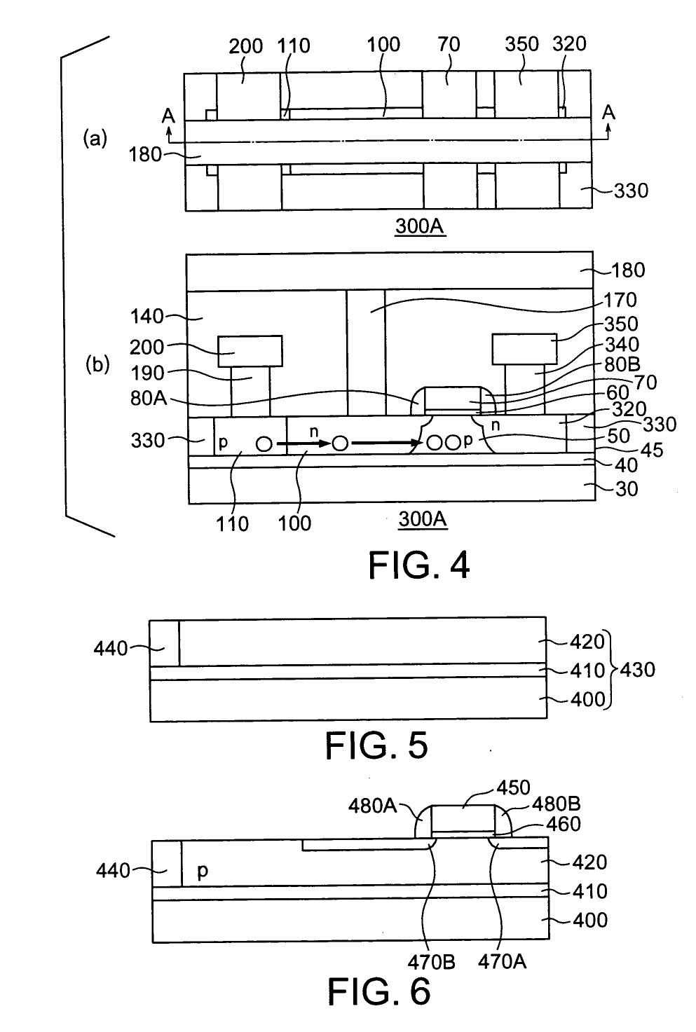

FIG. 3 shows the configuration of a memory cell array 310 wherein a source line 350 is independently formed for each of adjoining FBC 300 in the direction of the bit line 180 as a comparative example; and FIG. 4 shows the configuration of an FBC 300A by the comparative example. In these drawings, the elements identical to those shown in FIGS. 1 and 2 are denoted by the same numerals and characters, and the description thereof will be omitted.

FIG. 3 shows a top view of the region in the memory cell array 310 where four FBCs 300A to 300D are formed when viewed from above; FIG. 4(a) shows a top view of the region where an FBC 300A is formed when viewed from above; and FIG. 4(b) shows a vertical sectional view of the FBC 300A cut along line A-A.

In the case of the memory cell 310 in the comparative example, the N-type source region 320 of the FBC 300A is electrically isolated from the N-type source region 360 of the FBC 300B adjacent to the FBC 300A by an element isolating insulation film 330. Thereby, the occurrence of bipolar disturb wherein holes that have flowed into the N-type source region 320 flow into the P-type floating body (not shown) of the adjoining FBC 300B in the direction of the bit line 180 can be suppressed.

Incidentally, since the potential of the source line 350, which is a ground line, coupled to the N-type source region 320 via a contact plug 340, is 0 V, the source line 350 can be shared by the FBC 300A and the FBC 300B adjoining each other.

As in the first embodiment, after suppressing the occurrence of bipolar disturb, by sharing the N-type source region 90, the suicide 130B, the contact plug 150 and the source line 160 by FBCs 10A and 10B adjoining each other in the direction of the bit line 180, the cell size can be reduced by about 15% compared with the comparative example.

Next, a method for manufacturing an FBC 10A according to the first embodiment will be described referring to FIGS. 5 to 12. As FIG. 5 shows, an SOI (silicon on insulator) substrate 430 wherein an embedded insulation film 410 and a P-type semiconductor layer 420 are sequentially laminated on a semiconductor substrate 400 is prepared. The semiconductor substrate 400 and the P-type semiconductor layer 420 are composed of, for example, silicon. The thickness of the embedded insulation film 410 is, for example, 25 nm; and the thickness of the P-type semiconductor layer 420 is, for example, 55 nm.

An element isolating trench (not shown) is formed by etching the P-type semiconductor layer 420 using an STI (shallow trench isolation) method, and an element isolating insulation film 440 is formed by embedding an insulation film in the element isolating trench.

An oxynitride film formed by introducing several percent nitrogen in a thermal oxide film, and a polysilicon film are sequentially formed on the P-type semiconductor layer 420 and the element isolating insulation film 440. Then, for example, phosphorus (P) ions or the like are implanted into the polysilicon film to electrically activate the polysilicon film. As FIG. 6 shows, the polysilicon film and the oxynitride film are sequentially patterned using lithography and RIE to form a gate electrode 450 and a gate insulation film 460.

A resist mask having a desired pattern (not shown) is formed, and ions of phosphorus or the like are implanted using the resist mask and the gate electrode 450 as masks, then a heat treatment to diffuse phosphorus (P) is performed to form an N-type source extension region 470A and an N-type drain extension region 470B. In this case, phosphorus ions are implanted, for example, under conditions of an accelerating energy of 15 keV and a dose of 1×10¹⁵ cm⁻².

After forming an insulating film, such as a silicon nitride film on the entire surface of the semiconductor layer 420, sidewall insulation films 480A and 480B are formed on the sides of the gate electrode 450 using RIE.

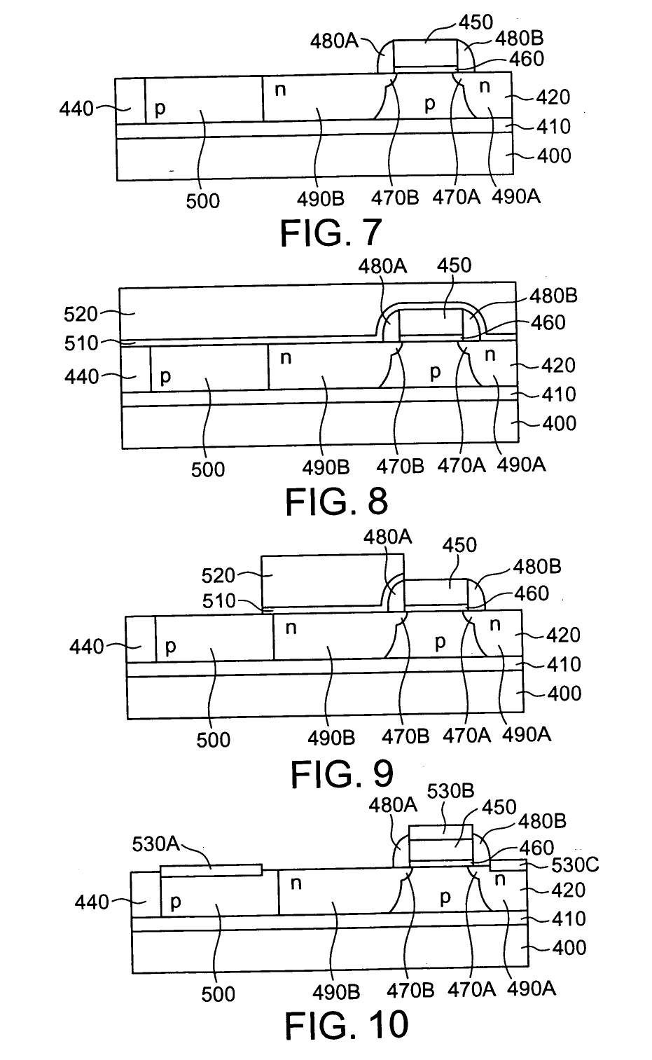

As FIG. 7 shows, a resist mask having a desired pattern (not shown) is formed, and ions of arsenic (As) or the like are implanted using the resist mask, the gate electrode 450, and sidewall insulation films 480A and 480B as masks, then a heat treatment to diffuse arsenic is performed to form an N-type source region 490A and an N-type drain region 490B. In this case, arsenic ions are implanted, for example, under conditions of an accelerating energy of 15 keV and a dose of 1×10¹⁵ cm⁻².

A resist mask having a desired pattern (not shown) is formed, and ions of boron (B) or the like are implanted using the resist mask as a mask, then a heat treatment to diffuse boron is performed to form a P-type emitter region 500. In this case, boron ions are implanted, for example, under conditions of an accelerating energy of 10 keV and a dose of 1×10¹⁵ cm⁻².

As FIG. 8 shows, a silicon nitride (SiN) film 510 and a silicon oxide (SiO₂) film 520 are sequentially formed on the entire surfaces of the element isolating insulation film 440, the semiconductor layer 420, the sidewall insulation films 480A and 480B, and the gate electrode 450.

As FIG. 9 shows, the silicon oxide film 520 and the silicon nitride film 510 are sequentially patterned using lithography and RIE to remove the silicon oxide film 520 and the silicon nitride film 510 formed on the element isolating insulation film 440, the P-type emitter region 500, the gate electrode 450, the sidewall insulation film 480B, and the N-type source region 490A, leaving only the silicon nitride film 510 and the silicon oxide film 520 formed on the N-type drain region 490B.

As FIG. 10 shows, the film of a metal, such as cobalt and nickel, is formed using a sputtering method and heat-treated to form silicide 530A to 530C on the surface portions of the P-type emitter region 500, the gate electrode 450, and the N-type source region 490A. Then, the unreacted metal film present on the silicon oxide film 520 is removed by, for example, wet etching, and the silicon nitride film 510 and the silicon oxide film 520 are removed.

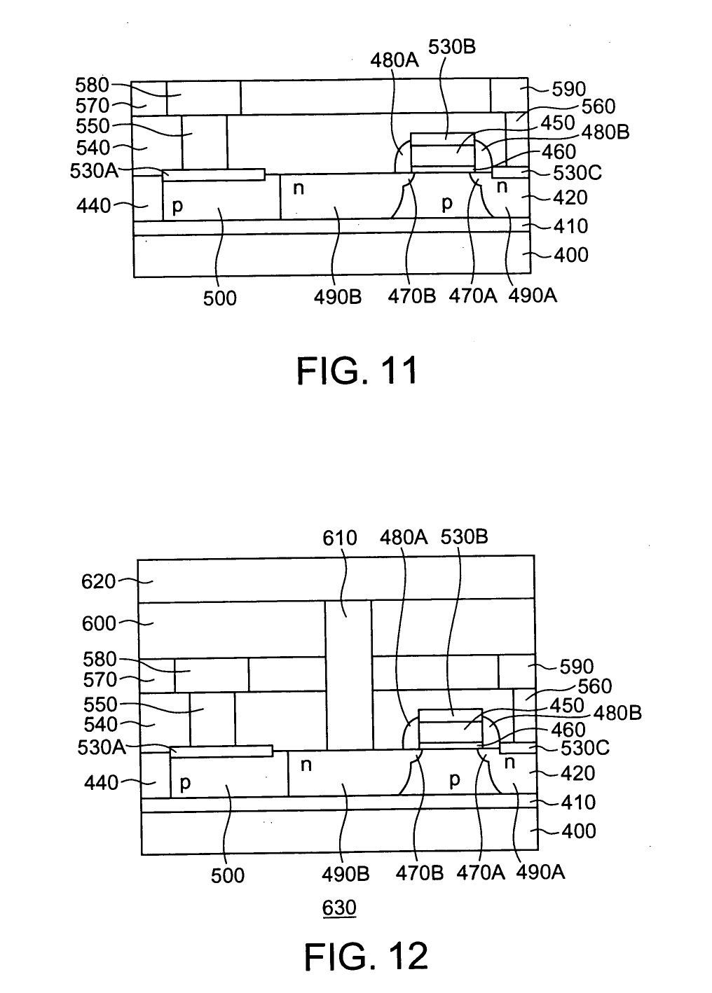

As FIG. 11 shows, after forming an interlayer insulation film 540 on the entire surface, desired regions are removed using lithography and RIE to form contact holes (not shown). Then, tungsten (W) is deposited so as to embed the contact holes to form a tungsten film. Thereafter, the tungsten film is planarized using a CMP method to form contact plug 550 and 560.

After forming an interlayer insulation film 570 on the entire surface, desired regions are removed using lithography and RIE to form a wiring trench (not shown). Then, copper (Cu) is deposited so as to embed the wiring trench to form a copper film. Thereafter, the copper film is planarized using a CMP method to form an emitter line 580 and a source line 590.

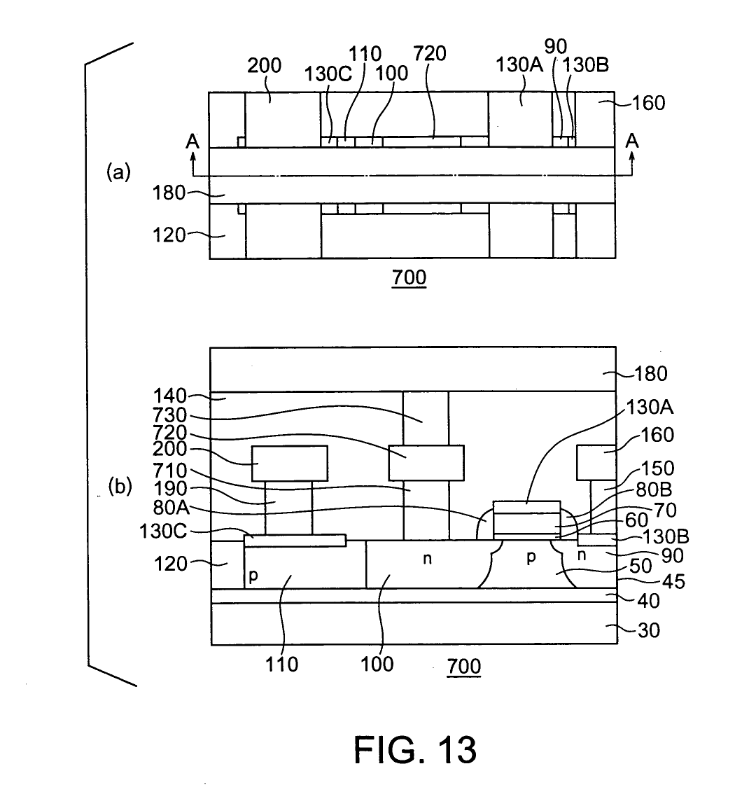

As FIG. 12 shows, after forming an interlayer insulation film 600 on the entire surface, desired regions in the interlayer insulation films 540, 570 and 600 are removed using lithography and RIE to form contact holes (not shown). Then, tungsten (W) is deposited so as to embed the contact holes to form a tungsten film. Thereafter, the tungsten film is planarized using a CMP method to form a contact plug 610.

After forming an interlayer insulation film (not shown) on the entire surface, desired regions are removed using lithography and RIE to form a wiring trench (not shown). Then, copper (Cu) is deposited so as to embed the wiring trench to form a copper film. Thereafter, by planarizing the copper film using a CMP method to form a bit line 620, an FBC 630 is completed.

(2) Second Embodiment

FIG. 13 shows the configuration of an FBC 700 according to the second embodiment of the present invention. FIG. 13(a) shows a top view of the FBC 700 viewed from above; and FIG. 13(b) shows a vertical sectional view when the FBC 700 is cut along the line A-A. Elements identical to those shown in FIG. 2 are denoted by the same reference numerals and characters, and the description thereof will be omitted.

Such an FBC 700 is constructed by forming a PNP bipolar transistor adjacent to the NMOSFET formed on an SOI substrate in the same manner as in the first embodiment.

In the case of the second embodiment, the N-type drain region 100 is coupled to a pad electrode 720 via a contact plug 710, and the pad electrode 720 is coupled to a bit line 180 via a contact plug 730.

The pad electrode 720 is formed in a wiring layer wherein a source line 160 and an emitter line 200 are formed. The contact plug 710 is formed when contact plugs 150 and 190 are formed by carrying out steps corresponding to FIG. 11 of the first embodiment.

In this case, the aspect ratio (depth/width) of the contact plug 710 formed on the N-type drain region 100 can be reduced to about a half of the aspect ratio of the contact plug 170 in the first embodiment. For example, when the aspect ratio of the contact plug 170 in the first embodiment is about 10, aspect ratio of the contact plug 710 in the second embodiment can be reduced to about 5.

In the case of the second embodiment, the semiconductor layer 45 is formed so as to be thin, for example, a thickness of about 55 nm. In this case, if the aspect ratio of the contact plug 170 is large, as in the first embodiment, when the contact hole is formed, the surface portion of the N-type drain region 100 may be removed by over-etching.

If the surface portion of the N-type drain region 100 is removed, and the N-type drain region 100 is further thinned, a problem that holes transferring from the P-type emitter region 110 to the P-type floating body 50 bond to electrons present in the N-type drain region 100 and disappear, and cannot reach the P-type floating body 50 may arise.

Whereas, in the second embodiment, by reducing the aspect ratio of the contact plug 710 formed on the N-type drain region 100 to about a half the aspect ratio of the contact plug 170 in the first embodiment, over-etching can be suppressed when contact holes are formed on the N-type drain region 100, and therefore, the thickness of the N-type drain region 100 can be secured. Thereby, holes transferring from the P-type emitter region 110 to the P-type floating body 50 can be prevented from bonding to electrons present in the N-type drain region 100 and disappearing.

According to the second embodiment, in the same manner as in the first embodiment, FBCs 700 adjacent to each other in the direction of the bit line 180 can share the N-type source region 90, the silicide 130B, the contact plug 150 and the source line 160, and thereby, the cell size can be reduced.

(3) Third Embodiment

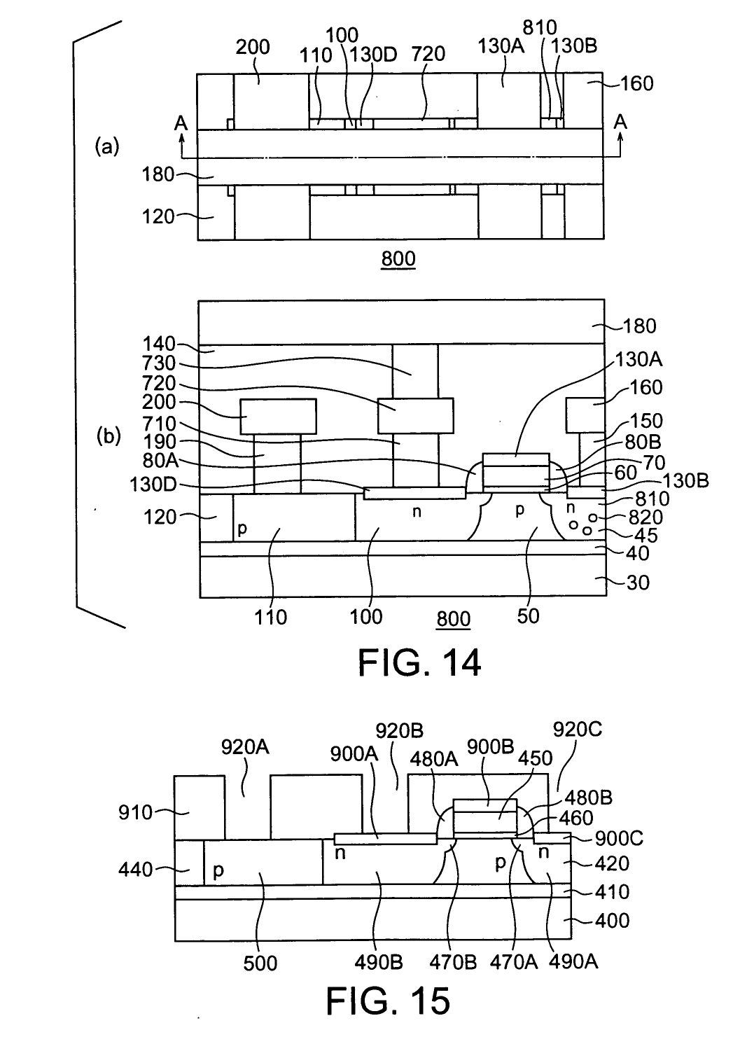

FIG. 14 shows the configuration of an FBC 800 according to the third embodiment of the present invention. FIG. 14(a) shows a top view of the FBC 800 viewed from above; and FIG. 14(b) shows a vertical sectional view when the FBC 800 is cut along the line A-A. Elements identical to those shown in FIG. 13 are denoted by the same reference numerals and characters, and the description thereof will be omitted.

Such an FBC 800 is constructed by forming a PNP bipolar transistor adjacent to the NMOSFET formed on an SOI substrate in the same manner as in the first embodiment.

In the case of the third embodiment, so-called crystal defects 820 are formed in the N-type source region 810. Crystal defects include linear line defects (dislocation) and spot-like point defects, and point defects include hole-type defects wherein no atoms are present at lattice points, and interstitial-atom-type defects wherein excessive atoms are present between lattice points.

Thereby, when data “1” is written in the FBC 800, even if holes accumulated in the P-type floating body 50 flow into the N-type source region 810, by the presence of crystal defects 820, they bond to electrons in the location where the crystal defects 820 are formed, and disappear.

Therefore, the occurrence of a phenomenon wherein holes go through the N-type source region 810 and flow into the P-type floating body (not shown) of the FBC adjacent to the N-type source region 810, known as bipolar disturb, can be suppressed.

As described above, by suppressing the occurrence of bipolar disturb by the crystal defects 820 formed in the N-type source region 810, there are no longer limitations in the thickness of the silicide 130B and the semiconductor layer 45 as in the first and second embodiments, and the design of a transistor becomes easier by that much.

In the case of the third embodiment, silicide 130D is formed on the surface of the N-type drain region 100. Even if the silicide 130D is thus formed on the surface of the N-type drain region 100, by increasing the thickness of the semiconductor layer 45, the phenomenon wherein holes transferring from the P-type emitter Region 110 to the P-type floating body 50 bond to electrons present in the N-type drain region 100 and disappear can be suppressed. In the case of the third embodiment, no silicide is formed on the surface of the P-type emitter region 110. No silicide 130A, 130B and 130D can be formed.

Furthermore, according to the third embodiment, in the same manner as in the first embodiment, FBCs 800 adjacent to each other in the direction of the bit line 180 can share the N-type source region 810, the silicide 130B, the contact plug 150 and the source line 160, and thereby, the cell size can be reduced.

Here, a method for manufacturing the FBC 800 according to the third embodiment will be described referring to FIGS. 15 to 18. In the case of the third embodiment, after carrying out the steps same as those in FIGS. 5 to 7 of the first embodiment, silicide 900A to 900C is formed on the surface portions of the N-type drain region 490B, the gate electrode 450 and the N-type source region 490A as FIG. 15 shows. Then, after forming an interlayer insulation film 910 on the entire surface, desired regions are removed using lithography and RIE, to form contact holes 920A to 920C.

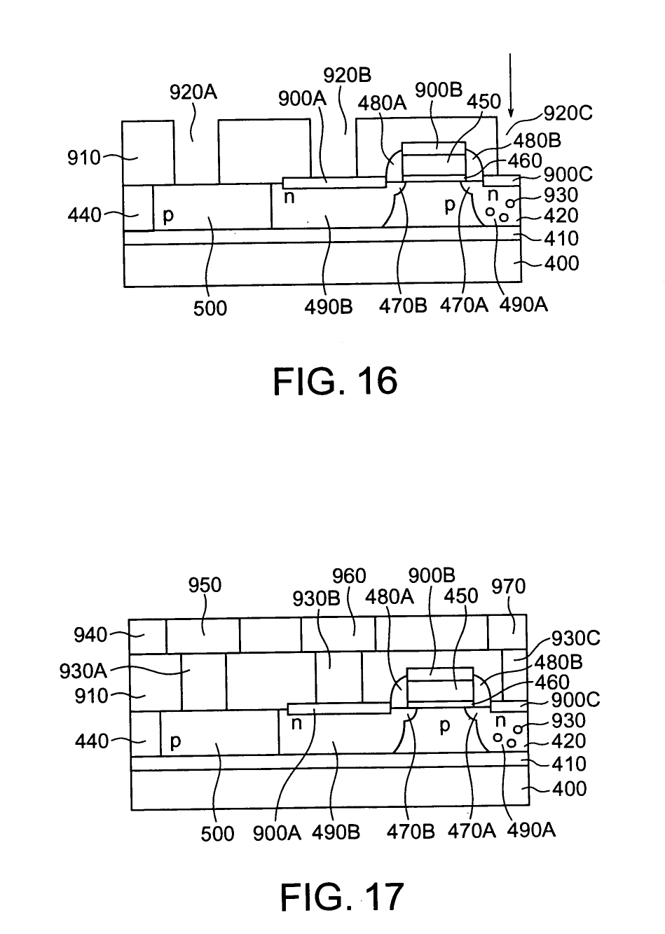

As FIG. 16 shows, ion implantation of germanium (Ge) is selectively performed to only the N-type source region 490A through the contact hole 920C to form crystal defects 930 in the N-type source region 490A. In this case, germanium ions are implanted, for example under conditions of an accelerating energy of 15 keV and a dose of 1×10¹⁵ cm⁻². Other various impurities, such as silicon (Si) and xenon (Xe) can also be implanted in place of germanium.

As FIG. 17 shows, tungsten (W) is deposited so as to embed the contact holes 920A to 920C to form a tungsten film. Thereafter, the tungsten film is planarized using a CMP method to form contact plugs 930A to 930C.

After forming an interlayer insulation film 940 on the entire surface, desired regions are removed using lithography and RIE, to form a trench (not shown), and copper (Cu) is deposited so as to embed the trench to form a copper film. Thereafter, the copper film is planarized using a CMP method to form an emitter line 950, a pad electrode 960 and a source line 970.

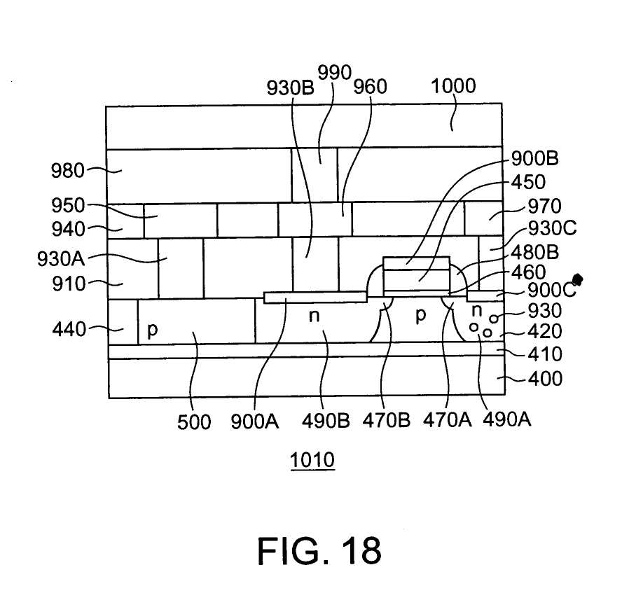

As FIG. 18 shows, after forming an interlayer insulation film 980 on the entire surface, desired regions in the interlayer insulation film 980 are removed using lithography and RIE, to form contact holes (not shown). Then, tungsten (W) is deposited so as to embed the contact holes to form a tungsten film. Thereafter, the tungsten film is planarized using a CMP method to form contact plugs 990.

After forming an interlayer insulation film (not shown) on the entire surface, desired regions are removed using lithography and RIE, to form a wiring trench (not shown). Then, copper (Cu) is deposited so as to embed the wiring trench to form a copper film. Thereafter, by planarizing the copper film using a CMP method to form a bit line 1000, an FBC 1010 is completed.

(4) Fourth Embodiment

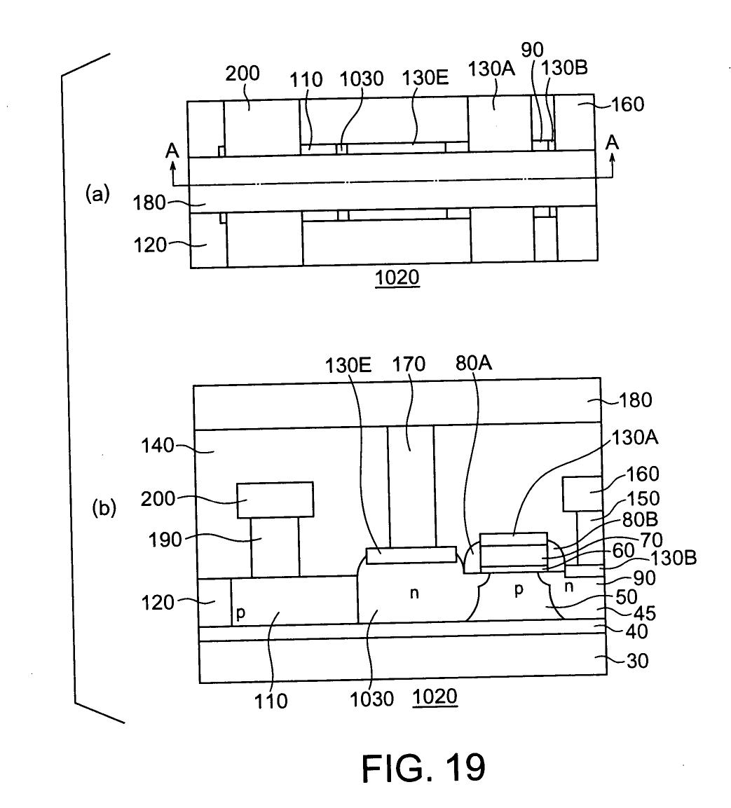

FIG. 19 shows the configuration of an FBC 1020 according to the fourth embodiment of the present invention. FIG. 19(a) shows a top view of the FBC 1020 viewed from above; and FIG. 19(b) shows a vertical sectional view when the FBC 1020 is cut along the line A-A. Elements identical to those shown in FIG. 2 are denoted by the same reference numerals and characters, and the description thereof will be omitted.

Such an FBC 1020 is constructed by forming a PNP bipolar transistor adjacent to the NMOSFET formed on an SOI substrate in the same manner as in the first embodiment.

In the case of the fourth embodiment, by selectively growing silicon on the N-type drain region 1030, the N-type drain region 1030 is formed so as to have a thickness larger than the thickness of the N-type source region 90. In this case, the thickness of the N-type source region 90 is about 30 nm, while the thickness of the N-type drain region 1030 can be about 100 nm.

Also in the case of the fourth embodiment, silicide 130E is formed on the surface of the N-type drain region 1030. Even if the silicide 130E is formed on the surface of the N-type drain region 1030 as described above, since the thickness of the N-type drain region 1030 is large, holes transferring from the P-type emitter region 110 to the P-type floating body 50 can be prevented from bonding to electrons present in the N-type drain region 1030 and disappearing. In the case of the fourth embodiment, no silicide is formed on the surface of the P-type emitter region 110.

According to the fourth embodiment, in the same manner as in the first embodiment, FBCs 1020 adjacent to each other in the direction of the bit line 180 can share the N-type source region 90, the silicide 130B, the contact plug 150 and the source line 160, and thereby, the cell size can be reduced.

(5) Other Embodiments

The above-described embodiments are examples, and the present invention is not limited thereto. For example, an NPN bipolar transistor can be formed adjacent to a PMOSFET formed on an SOI substrate.

What is claimed is:

1. A semiconductor memory device comprising:
a semiconductor layer of a first conductivity type formed above a semiconductor substrate via an embedded insulation film;
a gate electrode formed above the semiconductor layer via a gate insulation film;
a floating body region of a first conductivity type formed under the gate electrode in the semiconductor layer of a first conductivity type, which functions as a collector region of a first conductivity type;
a source region of a second conductivity type and a drain region of a second conductivity type formed on both sides of the floating body region in the semiconductor layer, the drain region functioning as a base region of a second conductivity type;
an emitter region of a first conductivity type formed in the semiconductor layer, adjacent to the side opposite to the side of the floating body region in the drain region; and
silicide formed at least on the surface portion of the source region.

2. The semiconductor memory device according to claim 1, wherein a distance between the silicide and the embedded insulation film in the source region is equal to or less than 80 nm.

3. The semiconductor memory device according to claim 1, wherein the thickness of the semiconductor layer is equal to or less than 100 nm.

4. The semiconductor memory device according to claim 1, further comprising:
a source line coupled to the source region via a plug for the source line;
an emitter line coupled to the emitter region via a plug for the emitter line;
a pad electrode coupled to the drain region via a plug for the pad electrode; and
a bit line coupled to the pad electrode via a plug for the bit line, formed in the higher position than the source line and the emitter line.

5. The semiconductor memory device according to claim 1, wherein the thickness of the drain region is larger than the thickness of the source region.

6. The semiconductor memory device according to claim 1, wherein the suicide is formed on the surface portions of the gate electrode, the source region, and the emitter region.

7. A semiconductor memory device comprising:
a semiconductor layer of a first conductivity type formed above a semiconductor substrate via an embedded insulation film;
a gate electrode formed above the semiconductor layer via a gate insulation film;
a floating body region of a first conductivity type formed under the gate electrode in the semiconductor layer of a first conductivity type, which functions as a collector region of a first conductivity type;
a source region of a second conductivity type and a drain region of a second conductivity type formed on both sides of the floating body region in the semiconductor layer, the drain region functioning as a base region of a second conductivity type; and
an emitter region of a first conductivity type formed in the semiconductor layer, adjacent to the side opposite to the side of the floating body region in the drain region, wherein the source region has a crystal defect.

8. The semiconductor memory device according to claim 7, further comprising:
silicide formed on the surface portions of the gate electrode, the source region and drain region.

9. The semiconductor memory device according to claim 7, wherein the crystal defect includes a line defect and a point defect.

10. A method for manufacturing a semiconductor memory device comprising:
forming a semiconductor layer of a first conductivity type above a semiconductor substrate via an embedded insulation film;
forming a gate electrode above the semiconductor layer via a gate insulation film;
forming a first mask having a desired pattern, forming a source region and a drain region of a second conductivity type by the ion implantation of an impurity into the semiconductor layer using the first mask and the gate electrode as masks;
forming a second mask having a desired pattern, forming an emitter region of a first conductivity type adjacent to the drain region by the ion implantation of an impurity into the semiconductor layer using the second mask; and
forming silicide at least on the surface portion of the source region.

11. The method for manufacturing a semiconductor memory device according to claim 10, wherein when the silicide are formed, the silicide is formed so that a distance between the silicide and the embedded insulation film in the source region becomes equal to or less than 80 nm.

12. The method for manufacturing a semiconductor memory device according to claim 10, wherein when the semiconductor layer is formed, the semiconductor layer is formed so that the thickness of the semiconductor layer becomes equal to or less than 100 nm.

13. The method for manufacturing a semiconductor memory device according to claim 10, further comprising:
forming a source line coupled to the source region via a plug for the source line, an emitter line coupled to the emitter region via a plug for the emitter line, and a pad electrode coupled to the drain region via a plug for the pad electrode; and
forming a bit line coupled to the pad electrode via a plug for the bit line on the position higher than the source line and the emitter line.

14. The method for manufacturing a semiconductor memory device according to claim 10, wherein when the source region and drain region are formed, the source region and drain region are formed so that the drain region is thicker than the source region.

15. The method for manufacturing a semiconductor memory device according to claim 10, wherein when the silicide is formed, the silicide is formed on the surface portions of the gate electrode, the source region and the emitter region.

16. The method for manufacturing a semiconductor memory device according to claim 10, further comprising:
forming an interlayer insulation film above the semiconductor layer and the gate electrode after forming the silicide;
forming a contact hole at least above the source region by removing a desired region of the interlayer insulation film; and
forming a crystal defect in the source region by the ion implantation of an impurity into the source region through the contact hole.

17. The method for manufacturing a semiconductor memory device according to claim 16, wherein when the silicide is formed, the silicide is formed on the surface portions of the gate electrode, and the source region and drain region.

18. The method for manufacturing a semiconductor memory device according to claim 16, wherein when the crystal defect is formed, a line defect or a point defect is formed in the source region.
